(19) United States
(12) Patent Application Publication
(10) Pub. No.: US 2020/0098649 A1
(43) Pub. Date: Mar. 26, 2020

(54) METHOD FOR PRODUCING SEMICONDUCTOR DEVICE

(71) Applicant: TOYODA GOSEI CO., LTD., Kiyosu-shi (JP)

(72) Inventor: Takahiro FUJII, Kiyosu-shi (JP)

(21) Appl. No.: 16/555,944

(22) Filed: Aug. 29, 2019

(30) Foreign Application Priority Data
Sep. 25, 2018 (JP) 2018-179437

(51) Int. Cl. H01L 21/66; H01L 29/66; H01L 21/02

(52) U.S. Cl. CPC H01L 22/12; H01L 29/66143; H01L 21/0262; H01L 21/02389; H01L 21/0254

(57) ABSTRACT

The present invention provides a method for producing a semiconductor device, which can evaluate the p-GaN crystal quality of the wafer for actually forming devices thereon. The method for producing a semiconductor device having a p-type GaN layer comprises forming a p-type layer on a wafer through MOCVD; measuring the PL spectrum of the p-type layer; and selecting wafers where the intensity ratio of the emission intensity in the blue band of 430 nm to 450 nm to the band edge emission intensity of the PL spectrum is not larger than 0.5. Thus, a semiconductor device exhibiting reduced contact resistance or leakage current can be produced.

### BACKGROUND OF THE INVENTION

### Field of the Invention

The present invention relates to a method for producing a Group III nitride semiconductor device having a p-type layer.

### Background Art

A Group III nitride semiconductor device such as pn diode and FET requires p-type low concentration GaN. To reduce the contact resistance of electrode to p-type low concentration GaN or suppress the leakage current, control is required to reduce the deep donor level compensating for acceptors. As disclosed in Non-Patent Document 1, DLTS (Deep Level Transient Spectroscopy) measurement reveals that this deep donor level is the energy level of Ec −0.5 eV (Ec is the energy level at the lower end of the conduction band).

Patent Document 1 discloses that the PL spectra of the n-type Group III nitride semiconductor layers on the substrates are measured, the substrates are screened by the yellow band emission intensity, thereby forming a Schottky barrier diode exhibiting suppressed leakage current. Patent Document 1 also discloses that the yellow band emission is caused by at least one impurity selected from a group consisting of carbon, hydrogen, and oxygen contained in Group III nitride semiconductor.
Patent Document 1: Japanese Patent Application Laid-Open (kokai) No. 2012-165020
Non-Patent Document 1: JOURNAL OF APPLIED PHYSICS 123, 161405(2018)

However, the crystal evaluation method disclosed in Patent Document 1, evaluates mainly the crystal quality of the n-type Group III nitride semiconductor, and cannot sufficiently evaluate the crystal quality of the p-type Group III nitride semiconductor.

Moreover, in the crystal quality evaluation of the p-type Group III nitride semiconductor by DLTS measurement, only the crystal quality inside a depletion layer of pn junction is evaluated and the crystal quality near the surface of the p-type layer cannot be evaluated. In the DLTS measurement, an electrode needs to be formed, measurement time is long because measurement is performed at a very low temperature, resulting in high measurement cost. Therefore, it was difficult to evaluate the wafer for actually forming devices thereon by DLTS measurement.

### SUMMARY OF THE INVENTION

In view of the foregoing, an object of the present invention is to provide a method for producing a semiconductor device, which can evaluate the p-GaN crystal quality of the wafer for actually forming devices thereon.

In a first aspect of the present invention, there is provided a method for producing a semiconductor device having a p-type GaN layer, the method comprising:

forming a p-type layer on a wafer through MOCVD;

exciting electrons in the p-type layer, and measuring an emission spectrum of a light emitted by relaxation of the electrons;

selecting wafers where the ratio of the emission intensity in the blue band from 430 nm to 450 nm to the band edge emission intensity of the emission spectrum is not larger than 0.5; and

continuing to form devices using the selected wafers.

A second aspect of the present invention is drawn to a specific embodiment of the method for producing a semiconductor device according to the first aspect of the invention, wherein the growth temperature of the p-type layer is preferably 1,100° C. to 1,150° C. Thereby, the crystal quality of the p-type layer can be further improved.

A third aspect of the present invention is drawn to a specific embodiment of the method for producing a semiconductor device according to the first or second aspect of the invention, wherein the semiconductor device may be a pn diode having a n⁺-GaN substrate, an n-type GaN layer formed on the substrate, and a p-type layer formed on the n-type layer.

According to the present invention, the p-GaN crystal quality can be evaluated using the wafer for actually forming devices thereon, and a semiconductor device exhibiting reduced contact resistance or leakage current can be formed by screening the wafers.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 shows the structure of a semiconductor device according to the first embodiment;

FIGS. 2A and 2B are sketches showing processes for producing the semiconductor device according to the first embodiment;

FIG. 3 is a flowchart showing processes for producing the semiconductor device according to the first embodiment;

FIG. 4 is a flowchart showing processes for producing the semiconductor device according to a variation of the first embodiment;

FIG. 5 is a graph showing the PL spectrum of the p-type layer 12;

FIG. 6 is a graph showing the relationship between I_{BL}/I_{NBE} and growth temperature of p-type layer 12;

FIG. 7 is a graph showing the relationship between I_{BL}/I_{NBE} and hole concentration;

FIG. 8 is a graph showing the relationship between reverse voltage and leakage current;

FIG. 9 is a graph showing the relationship between I_{BL}/I_{NBE} and leakage current; and

FIG. 10 is a graph showing the relationship between I_{BL}/I_{NBE} and contact resistance.

### DETAILED DESCRIPTION OF PREFERRED EMBODIMENTS

Specific embodiments of the present invention will next be described with reference to the drawings. However, the present invention is not limited to the embodiments.

### First Embodiment

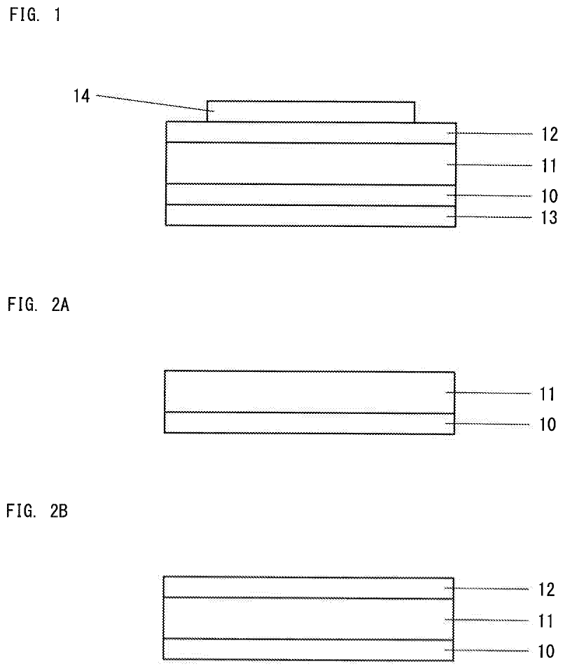

FIG. 1 shows the structure of a semiconductor device according to the first embodiment. The semiconductor device according to the first embodiment comprises a GaN substrate 10, an n-type GaN layer 11, a p-type GaN layer 12, an n-electrode 13, and a p-electrode 14.

The substrate 10 is made of n⁺-GaN having a Si concentration of 1.0×10¹⁸/cm³ to 1.0×10²⁰/cm³, and has a main surface c-plane. The substrate may be a conductive substrate made of any material as long as GaN can be epitaxially grown thereon. For example, SiC or Si may be used.

The n-type layer 11 is disposed on the substrate 10, and is made of n-GaN having a Si concentration of 1×10¹⁵/cm³ to 1×10¹⁷/cm³. The thickness of the n-type layer 11 is 1 μm to 20 μm.

The p-type layer 12 is disposed on the n-type layer 11, and is made of p-GaN having a Mg concentration of 5×10¹⁷/cm³ to 5×10¹⁹/cm³. The thickness of the p-type layer 12 is 0.1 μm to 2 μm.

The n-electrode 13 is formed on the back side of the substrate 10 (the surface opposite to the surface on which the n-type layer 11 is formed). The n-electrode 13 is an ohmic electrode made of Ti/Al. Any other material capable of forming ohmic contact with n⁺-GaN may be used.

The p-electrode 14 is formed on the p-type layer 12. The p-electrode 14 is an ohmic electrode made of Ni. Any other material capable of forming ohmic contact with p-GaN may be used. For example, Pd or Pt may be used.

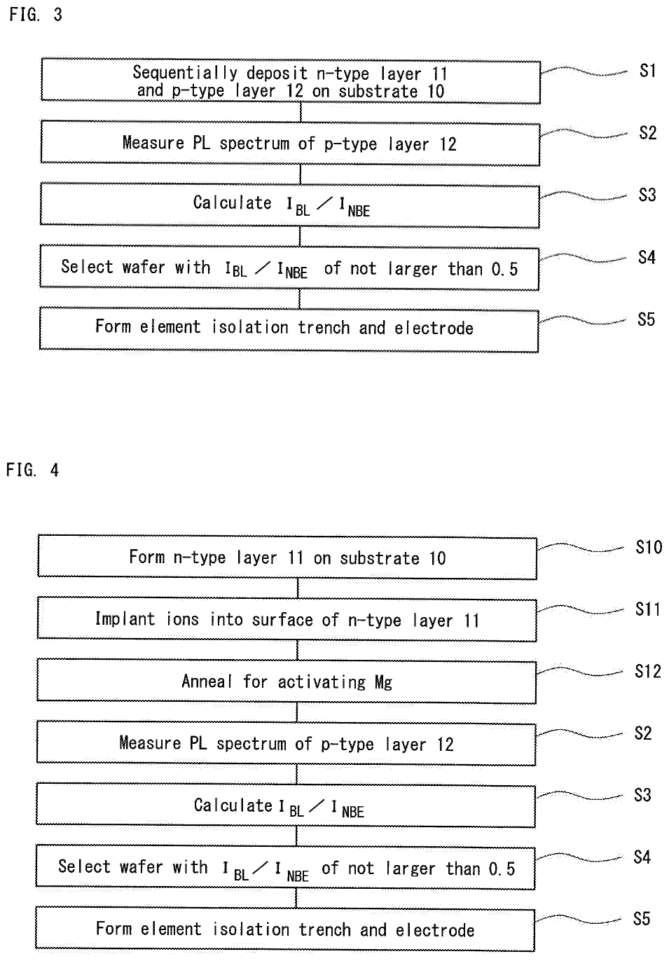

Next will be described processes for producing the semiconductor device according to the first embodiment with reference to FIGS. 2A, 2B, and 3.

Firstly, an n-type GaN layer 11 is formed through MOCVD on an n⁺-GaN substrate 10 (refer to FIG. 2A). The growth temperature is 1,050° C. to 1,150° C., and the V/III ratio is 1500 to 4000. Hereinafter, the V/III ratio is the molar ratio (flow ratio) of Ga source gas to nitrogen source gas supplied in an MOCVD chamber. Ga source gas is, for example, trimethylgallium (TMG), and nitrogen source gas is, for example, ammonia.

Subsequently, a p-type Mg-doped GaN layer 12 is formed through MOCVD on the n-type layer 11 (refer to FIG. 2B and step S1 of FIG. 3). The growth temperature is 1,050° C. to 1,150° C., and the V/III ratio is 1000 to 4000. The impurity concentration of the p-type layer 12 can be controlled by controlling the V/III ratio. Annealing is performed to activate Mg contained in the p-type layer 12. The growth temperature is particularly preferably 1,100° C. to 1,150° C. Within this range, the crystal quality of the p-type layer 12 can be improved.

Next, the PL spectrum of the p-type layer 12 is measured (step S2 of FIG. 3). More specifically, the surface of the p-type layer 12 is irradiated with the excitation light, the light scattered by the surface of the p-type layer 12 is led to a spectroscope, and the spectrum is measured by the spectroscope. The PL spectrum is easily measured at a room temperature, which is desirable.

Although the PL spectrum is measured in the first embodiment, any method may be used as long as it measures the spectrum of a light emitted at the time when electrons excited from the ground state in the p-type layer 12 are transited to the ground state. For example, the CL spectrum may be measured.

Next, the intensity ratio I_{BL}/I_{NBE} of the blue band emission intensity to the band edge emission intensity of the PL spectrum is calculated (step S3 of FIG. 3). That is, the blue band emission intensity is normalized by the band edge emission intensity. The PL spectrum has a strong peak at a wavelength of 365 nm (3.4 eV), and this peak intensity is the band edge emission intensity. The blue band ranges from 430 nm to 450 nm. The blue band emission intensity is defined as the maximum emission intensity in the blue band.

Based on this intensity ratio I_{BL}/I_{NBE}, the wafers are sorted into wafers that are sent to the next step and wafers for which device formation is stopped (step S4 of FIG. 3). The criterion for screening is whether the intensity ratio I_{BL}/I_{NBE} of the blue band emission intensity to the band edge emission intensity of the PL spectrum is not larger than 0.5. For the wafers having an intensity ratio of not larger than 0.5, next step is performed. For the wafers having an intensity ratio of larger than 0.5, device formation is stopped and such wafers are collected.

The crystal quality of the p-type layer 12, specifically the crystal quality of the surface of the p-type layer 12 can be evaluated by measuring the PL spectrum of the p-type layer 12 and evaluating the blue band emission intensity. From the inventors' study, it was found that in case of p-GaN, the crystal quality cannot be sufficiently evaluated in the conventional evaluation of the yellow band emission intensity (emission caused by the level formed due to impurity), sometimes resulting in devices having a large contact resistance or a high leakage current. It is assumed that in case of p-GaN, the level formed due to other factors (for example, crystal defect such as point defect or dislocation) has more effect on current leakage on the surface of p-GaN than the level formed due to impurity. On the other hand, in the evaluation of the blue band emission intensity, emission caused by the level formed due to factors other than impurity can be evaluated. Therefore, as in the first embodiment, the crystal quality of the surface of the p-type layer 12 can be evaluated by evaluating the blue band emission intensity.

The reason why the criterion for screening the wafers is whether the intensity ratio I_{BL}/I_{NBE} of the blue band emission intensity to the band edge emission intensity of the PL spectrum is not larger than 0.5, is because the semiconductor device formed using the wafer with an intensity ratio of not larger than 0.5 can considerably reduce the leakage current and the contact resistance, compared to the semiconductor device formed using the wafer with an intensity ratio of larger than 0.5.

For the selected wafers, device isolation trenches (not illustrated) are formed by dry etching from the p-type layer 12 side. A p-electrode 14 is formed on the p-type layer 12 and an n-electrode 13 is formed on the back side of the substrate 10 through vapor deposition or sputtering (step S5 of FIG. 3). Thus, the semiconductor device according to the first embodiment shown in FIG. 1 is produced.

According to the method for producing the semiconductor device of the first embodiment, the crystal quality of the p-type layer 12 can be evaluated using the wafer for actually forming devices thereon, and the wafers are screened based on the evaluation, thereby producing a semiconductor device exhibiting reduced contact resistance or leakage current. Moreover, the hole concentration of the p-type layer 12 can be controlled. Conventionally, the emission caused by the level formed due to factors other than impurity could not be evaluated for a short time at low cost. However, in the first embodiment, the crystal quality of the p-type layer 12 can be evaluated in a short time at low cost.

The semiconductor device according to the first embodiment is a pn diode. However, the present invention is not limited thereto, and may be applied to any semiconductor device having a p-GaN structure. The present invention may also be applied to, for example, FET. The semiconductor device according to the first embodiment has a vertical conductive structure. However, the semiconductor device may have a horizontal conductive structure.

The PL spectrum of the p-type layer 12 may be measured at any timing before the formation of the n-electrode 13 and the p-electrode 14 after the formation of the p-type layer 12. However, the wafers are preferably screened in an earlier stage of the production process. The PL spectrum is also preferably measured in the earlier stage of the production process. Therefore, the PL spectrum is preferably measured before the device isolation step just after the crystal growth of GaN as in the first embodiment.

In the first embodiment, Mg is introduced into the GaN crystal by supplying the p-type dopant gas in the MOCVD chamber. However, Mg may be introduced directly into a target region by ion implantation, or Mg may be introduced into a target region by annealing to diffuse Mg after ion implantation of Mg into a region other than the target region.

FIG. 4 shows processes for forming a p-type layer 12 by ion implantation. Firstly, an n-type layer 11 is formed on a substrate 10 (step S10 of FIG. 4), after that, Mg is ion-implanted into the surface of the n-type layer 11 (step S11 of FIG. 4). Subsequently, annealing is performed to activate the ion-implanted Mg, and a p-type layer 12 is formed (step S12 of FIG. 4). The subsequent steps are the same as steps S2 to S5 of FIG. 3.

### EXPERIMENTAL EXAMPLES

Next will be described various experimental examples regarding the first embodiment.

### Experimental Example 1

Firstly, an n-type layer 11 and a p-type layer 12 were sequentially deposited on a substrate 10 through MOCVD. The n-type layer 11 is formed at a V/III ratio of 2500 and a Si concentration of 1×10¹⁶/cm³, so as to have a thickness of 10 μm. The p-type layer 12 is formed at a V/III ratio of 1500 and a Mg concentration of 2×10¹⁸/cm³, so as to have a thickness of 1 μm. A plurality of wafers was produced, with the growth temperatures of the n-type layer 11 and the p-type layer 12 varied stepwise from 1,040° C. to 1,180° C. Annealing was performed to activate Mg contained in the p-type layer 12. Annealing was performed at a temperature of 700° C. for five minutes in a mixture gas of nitrogen and oxygen (the volume ratio of oxygen in the mixture gas is 5%).

The PL spectrum of the thus-formed p-type layer 12 was measured. A He—Cd laser (with a wavelength of 325 nm and an output power of 4 mW) was used as the excitation light source. However, when the growth temperature is 1,040° C., pits were generated on the surface of the p-type layer 12. When the growth temperature is 1,180° C., roughness was generated on the surface of the p-type layer 12. Therefore, the PL spectrum was not measured in these cases.

The hole concentration of the p-type layer 12 was measured by a four-terminal method. The electrode for measuring the hole concentration is made of Ni having a thickness of 100 nm, and the electrode was alloyed at a temperature of 550° C. for five minutes in an nitrogen atmosphere.

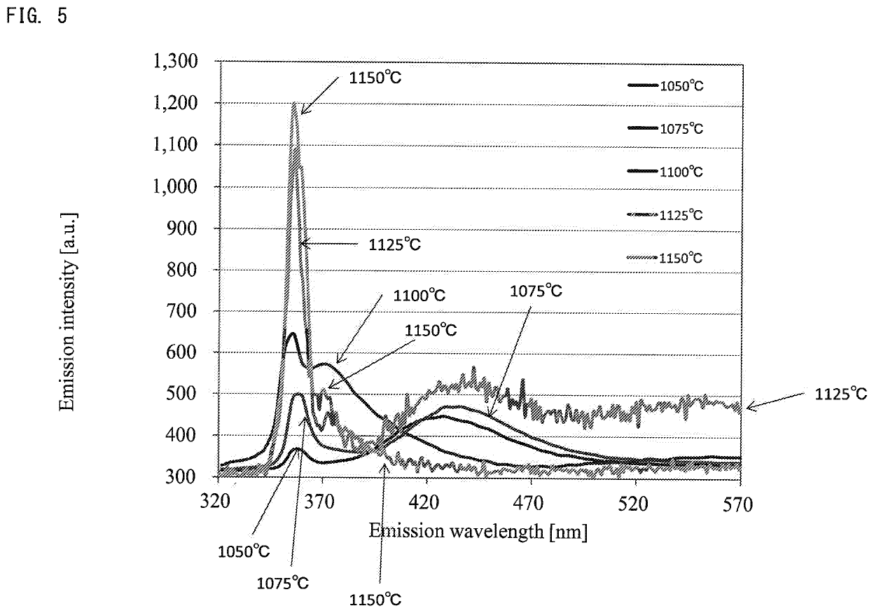

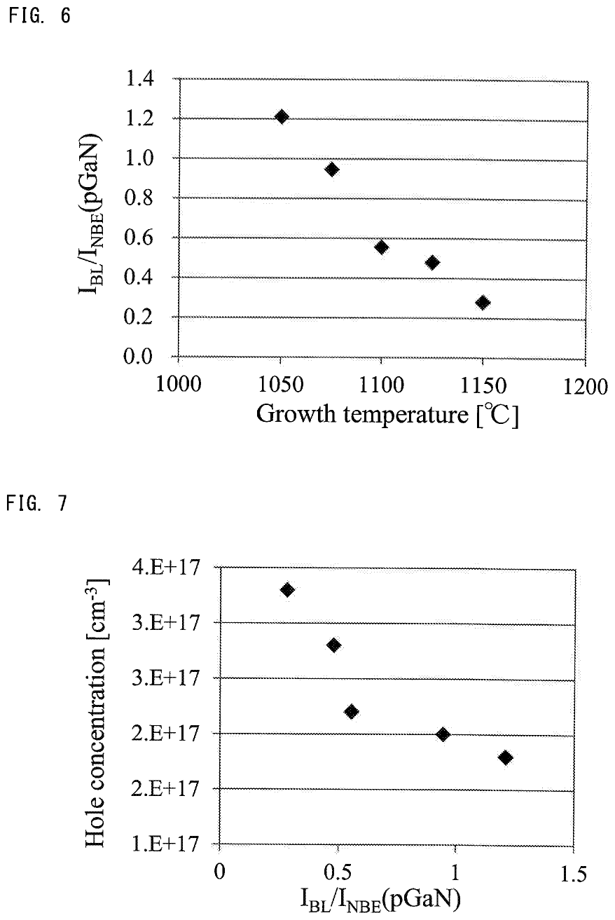

FIG. 5 is a graph showing the PL spectrum of the p-type layer 12. FIG. 6 is a graph showing the relationship between the intensity ratio I_{BL}/I_{NBE} of the PL spectrum to the emission intensity in the blue band (430 nm to 450 nm) to the band edge emission intensity and the growth temperature of the p-type layer 12. The intensity ratios I_{BL}/I_{NBE} 1.21, 0.95, 0.56, 0.48, and 0.28 are obtained at the growth temperatures 1,050° C., 1,075° C., 1,100° C., 1,125° C., and 1,150° C., respectively.

As shown in FIG. 5, peaks were observed at a wavelength of 365 nm, which means band edge emission, and emissions were also observed in the blue band of 430 nm to 450 nm. Since the blue band emission has a wavelength band different from that of the yellow band emission caused by the level formed due to impurity, the blue band emission is assumed to be caused by the level formed due to factors other than impurity.

As shown in FIG. 6, the higher the growth temperature, the lower the intensity ratio I_{BL}/I_{NBE}. It is assumed that the higher the growth temperature, the lower the level formed due to factors other than impurity, for example, crystal defect such as point defect or dislocation.

FIG. 7 is a graph showing the relationship between the intensity ratio I_{BL}/I_{NBE} and the hole concentration. The hole concentrations 3.0×10¹⁷, 2.8×10¹⁷, 2.2×10¹⁷, 2.0×10¹⁷, and 1.8×10¹⁷ are obtained at the intensity ratios I_{BL}/I_{NBE} 0.28, 0.48, 0.56, 0.95, and 1.21, respectively. The larger the intensity ratio I_{BL}/I_{NBE}, the lower the hole concentration. Especially when the intensity ratio I_{BL}/I_{NBE} exceeded 0.5, the hole concentration was remarkably reduced. This implies that when the intensity ratio I_{BL}/I_{NBE} exceeds 0.5, the hole concentration of the p-type layer 12 is hardly controlled. It is particularly preferable that the intensity ratio I_{BL}/I_{NBE} is not larger than 0.48 and the growth temperature is not lower than 1,125° C.

### Experimental Example 2

Similarly as in Experimental Example 1, an n-type layer 11 and a p-type layer 12 were deposited on a substrate 10, and the PL spectrum was measured. After that, device isolation trenches were formed by dry etching, a p-electrode 14 was formed on the p-type layer 12, and an n-electrode 13 was formed on the back side of the substrate 10. A plurality of devices was formed, with the growth temperatures of the n-type layer 11 and the p-type layer 12 varied stepwise from 1,040° C. to 1,180° C. The leakage current of the thus-produced pn diode was measured and also the contact resistance of the p-electrode 14 was measured.

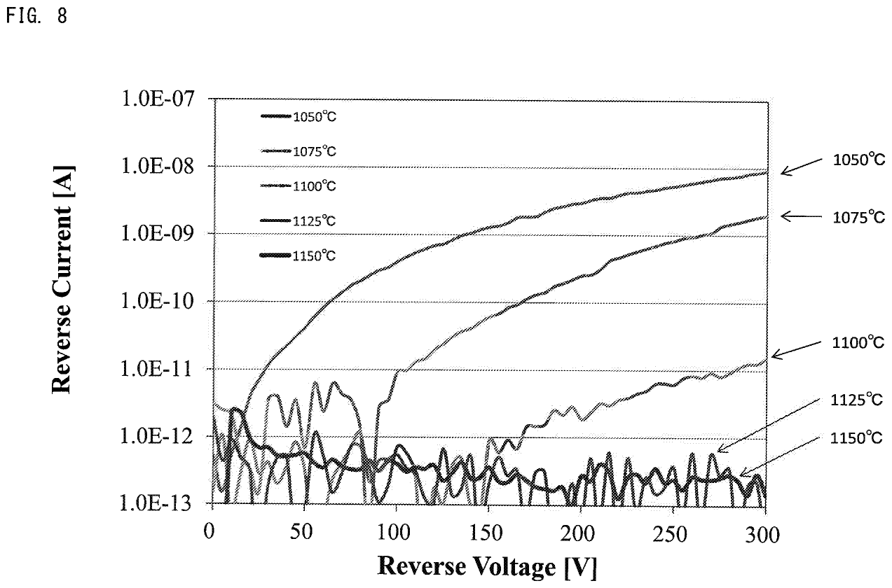

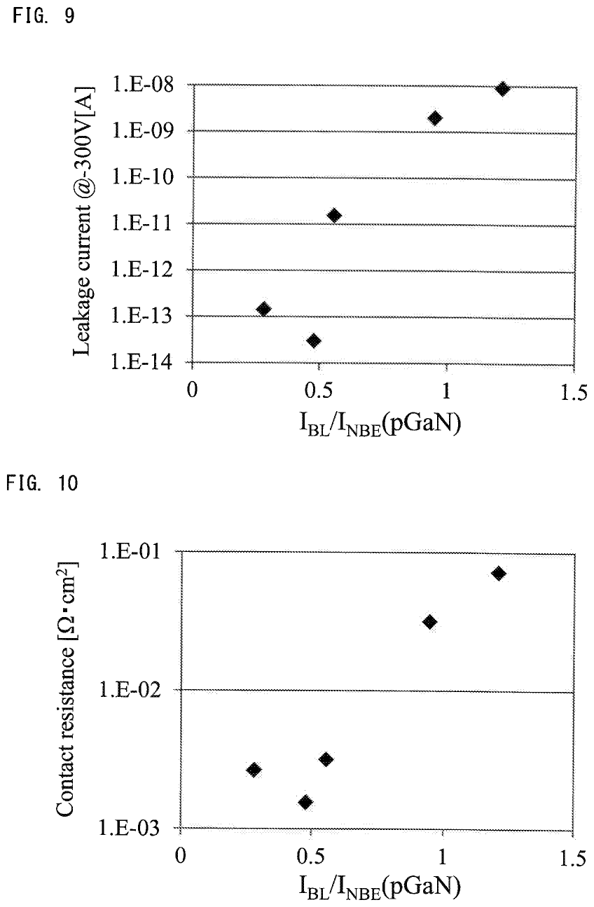

FIG. 8 is a graph showing the leakage current when a reverse voltage was applied to the pn diode. FIG. 9 is a graph showing the relationship between the intensity ratio I_{BL}/I_{NBE} and the leakage current when the reverse voltage is 300 V. The leakage currents 9.0×10⁻⁹ A, 2.0×10⁻⁹A, 1.5×10⁻¹¹ A, 3.0×10⁻¹⁴ A, and 1.4×10⁻¹³ A are obtained at the intensity ratios I_{BL}/I_{NBE} 1.21, 0.95, 0.56, 0.48, and 0.28, respectively.

FIG. 8 reveals that the lower the growth temperature, the larger the leakage current tends to be. FIG. 9 reveals that when the intensity ratio I_{BL}/I_{NBE} is not larger than 0.5, the leakage current is kept at a low level of not larger than 1×10⁻¹² A, and that when the intensity ratio I_{BL}/I_{NBE} exceeds 0.5, the leakage current exceeds 1×10⁻¹¹, and rapidly increases. In the present experiment, the measuring lower limit of leakage current is 1×10⁻¹³ A. The value smaller than this is uncertain. Accordingly, the intensity ratio I_{BL}/I_{NBE} is preferably not larger than 0.5, more preferably not larger than 0.48.

FIG. 10 is a graph showing the relationship between the intensity ratio I_{BL}/I_{NBE} and the contact resistance of the p-electrode 14. The contact resistances 7.2×10⁻² Ωcm², 3.2×10⁻² Ωcm², 3.2×10⁻³ Ωcm², 1.6×10⁻³ Ωcm², and 2.7×10⁻³ Ωcm² are obtained at the intensity ratios I_{BL}/I_{NBE} 1.21, 0.95, 0.56, 0.48, and 0.25, respectively.

As shown in FIG. 10, the contact resistance has the same tendency as the leakage current. It was found that when the intensity ratio I_{BL}/I_{NBE} is not larger than 0.5, the contact resistance is kept at a low level, and that when the intensity ratio I_{BL}/I_{NBE} exceeds 0.5, the contact resistance rapidly increases. Accordingly, the intensity ratio I_{BL}/I_{NBE} is preferably not larger than 0.5, more preferably not larger than 0.48.

From the Experimental Examples 1 and 2, it was found that the intensity ratio I_{BL}/I_{NBE} is appropriate as a crystal quality evaluation index of the p-type layer 12, and the leakage current and the contact resistance of the pn diode can be reduced by selecting the wafers having an intensity ratio I_{BL}/I_{NBE} of preferably not larger than 0.5, more preferably not larger than 0.48 for forming devices. The hole concentration of the p-type layer 12 can be controlled by the intensity ratio I_{BL}/I_{NBE}. When the intensity ratio I_{BL}/I_{NBE} is preferably not larger than 0.5, more preferably not larger than 0.48, the hole concentration can be appropriately controlled.

The present invention can be employed in production of Group III nitride semiconductor power device and others.

What is claimed is:

1. A method for producing a semiconductor device having a p-type GaN layer, the method comprising:
forming a p-type layer on a wafer through MOCVD;
exciting electrons in the p-type layer, and measuring an emission spectrum of a light emitted by relaxation of the electrons;
selecting wafers where the ratio of the emission intensity in the blue band of 430 nm to 450 nm to the band edge emission intensity of the emission spectrum is not larger than 0.5; and
continuing to form devices using the selected wafers.

2. The method for producing a semiconductor device according to claim 1, wherein the growth temperature of the p-type layer is 1,100° C. to 1,150° C.

3. The method for producing a semiconductor device according to claim 1, wherein the semiconductor device is a pn diode having a n⁺-GaN substrate, an n-type GaN layer formed on the substrate, and a p-type layer formed on the n-type layer.

4. The method for producing a semiconductor device according to claim 2, wherein the semiconductor device is a pn diode having a n⁺-GaN substrate, an n-type GaN layer formed on the substrate, and a p-type layer formed on the n-type layer.
